(19) United States
(12) Patent Application Publication
(10) Pub. No.: US 2003/0012899 A1
(43) Pub. Date: Jan. 16, 2003

(54) Doped silica glass crucible for making a silicon ingot

(75) Inventors: Katsuhiko Kemmochi, Vancouver, WA (US); Robert Mosier, Vancouver, WA (US); Paul Spencer, Stevenson, WA (US)

Correspondence Address: MARGER JOHNSON & MCCOLLOM PC, 1030 SW MORRISON STREET, PORTLAND, OR, 97205, US

(73) Assignee: Heraeus Shin-Etsu America, Camas, WA

(21) Appl. No.: 10/174,875

(22) Filed: Jun. 18, 2002

Related U.S. Application Data
(63) Continuation-in-part of application No. 09/906,879, filed on Jul. 16, 2001.
(63) Continuation-in-part of application No. 10/021,631, filed on Dec. 12, 2001.

(51) Int. Cl. B32B 1/02; A47G 19/22; B28B 21/00; B29D 22/00; B29D 23/00; B28B 23/08; B32B 1/08; B65D 1/00; F16L 9/10; C30B 1/00

(52) U.S. Cl. 428/34.6; 117/200; 117/900

(57) ABSTRACT

A crucible adapted for use in formation of a silicon crystal comprises a crucible wall including a bottom wall and a side wall. An inner layer is formed on an inner portion of the crucible wall and has distributed therein a crystallization agent containing an element selected from the group consisting of barium, aluminum, titanium and strontium.

The crucible is made by forming a bulk grain layer on an interior surface of a rotating crucible mold, generating a high-temperature atmosphere in the crucible cavity, and introducing inner grain and crystallization agent into the high-temperature atmosphere, fusing the inner grain to form a doped inner layer.

The inner layers of crucibles disclosed herein are adapted to, when heated, crystallize according to any of three operating modes that retain a smooth inner surface and reinforce the structural rigidity of the crucible walls.

### CROSS REFERENCE TO RELATED APPLICATIONS

This application is a continuation-in-part of U.S. application Ser. No. 09/906,879, filed on Jul. 16, 2001, and U.S. application Ser. No. 10/021,631, filed on Dec. 12, 2001.

### BACKGROUND OF THE INVENTION

The present invention is related to the field of silica crucibles, and more specifically to a silica crucible having a multi-layer wall in which one or more of the wall layers are doped with a crystallization agent.

A Czochralski (CZ) process is known in the art for producing single crystalline silicon ingots, from which silicon wafers are made for use in the semiconductor industry. In a CZ process, polycrystalline silicon is charged in a crucible typically housed within a susceptor. A single silicon crystal is pulled from the molten silicon.

Currently, the semiconductor industry is trending toward larger-diameter wafers, e.g., 300 mm in diameter. To grow silicon ingots of this diameter, the CZ process operating time must be increased, sometimes to more than one hundred hours. As well, decreasing the crystal pulling rate, while minimizing the frequency of structural defects in the silicon crystal, in turn prolongs the CZ run time and further emphasizes the need to improve the useful life of the crucible.

Further, some silicon ingot manufacturers perform multiple silicon crystal “pulls” during a single CZ-process. In such uses, a portion of the crucible side wall is alternately covered by the melt, exposed to atmosphere as the melt level drops, then covered again as the next silicon charge is melted to begin another ingot pull. The inner surface of a crucible so used is subjected to high stress for a longer time period, making more important the inner surface integrity.

At operating temperatures, the innermost portion of a conventional silica crucible reacts with the silicon melt. The inner surface of the crucible typically undergoes a change in morphology and roughens during operation in a CZ run. As well, the high heat of a CZ process softens the walls of the crucible and increases the risk of crucible structural deformation.

Roughening on the crucible inner surface can cause crystal flaws in the ingot being pulled. When a major portion of the crucible inner surface roughens, crystalline structure is disrupted at the crystal-melt interface and silicon crystal pulling must be ceased. Roughening therefore renders the crucible unfit for continued use in silicon ingot manufacture.

Devitrification (i.e., crystallization) occurs in a shallow layer on the innermost portion of the crucible. The silica glass of a conventional crucible experiences a volume change as it crystallizes, creating stress at the vitreous phase-crystalline phase interfaces. Such stress is relieved by micro-scale deformation in the glassy phase of the crucible, deteriorating the smoothness of the inner surface.

Crucible devitrification typically occurs as circular patterns (“rosettes”) that develop on the innermost portion of the crucible. The rosettes have been determined to be surrounded by cristobalite. The center of the rosette has a rough surface that is either not covered by cristobalite or covered by a very thin cristobalite layer.

During a CZ-process, rosettes form on the crucible inner surface, and the central surface regions of the rosettes roughen. The rosettes grow and merge, increasing the rough surface area of the crucible inner surface.

Additionally, the crucible inner layer can partially dissolve into the silicon melt during the CZ process. Silicon and oxygen, the main components of a silica crucible, do not cause flaws in the growing silicon ingot. However, impurities in the inner layer can be transferred to the silicon melt during this process and be incorporated into the silicon crystal.

Prior art attempts to control devitrification of a crucible inner surface have included coatings containing crystallization promoters, such as U.S. Pat. No. 5,976,247. In that reference, a devitrification promoting solution is applied to the surface of a conventional, commercially available crucible. Upon heating to 600° C. or greater, the inner surface is said to crystallize to some degree.

However, this surface coating technique has several drawbacks. It addresses only promotion of silica crystallization. Retardation of crystallization, and preservation of the glass of the crucible inner surface, cannot be obtained in the coated crucible. The coating technique also lacks control over the depth and rate of crystallization of the crucible. A coated crucible also must be specially handled, as inadvertent contact can result in removal of the crystallization promoter coating from the inner surface.

### BRIEF DESCRIPTION OF THE DRAWINGS

FIG. 1 is a cross-sectional view of one embodiment of a silica glass crucible constructed according to the present disclosure.

FIG. 2 is an enlarged, partial cross-sectional view of the wall of the silica glass crucible shown in FIG. 1.

FIG. 3 is an enlarged, partial cross-sectional view of the wall of a first alternative embodiment of a silica glass crucible constructed according to the present disclosure.

FIG. 4 is an enlarged, partial cross-sectional view of the wall of a second alternative embodiment of a silica glass crucible constructed according to the present disclosure.

FIGS. 5-9 are diagrams showing methods for making silica glass crucibles as described herein.

FIGS. 10-12 are partial plan views of an inner surface of a silica glass crucible of the prior art, showing rosettes occurring during a CZ-process.

FIGS. 13-14 are partial, enlarged top and cross-sectional views, respectively, of the prior art crucible wall shown in FIG. 10.

FIGS. 15-16 are partial, enlarged top and cross-sectional views, respectively, of an inner surface of a silica glass crucible according to the “CORONA” embodiment of the present invention.

FIGS. 17-19 are partial, enlarged top views of the inner surface of a “SMOOTH” embodiment crucible.

FIGS. 20-21 are partial, enlarged top and cross-sectional views, respectively, of the crucible wall and silica crystallization rosette depicted in FIG. 17.

### DETAILED DESCRIPTION OF THE PREFERRED EMBODIMENT(S)

Crucible disclosed herein are adapted for use in formation of silicon crystals. The crucibles include a wall having an inner layer formed on an inner aspect of the crucible wall. Distributed within the inner layer is a crystallization agent that contains an element selected from the group consisting of barium, aluminum, titanium and strontium.

The inner layers of crucibles disclosed herein are adapted to, when heated, crystallize according to any of three operating modes that retain a smooth inner surface and reinforce the structural rigidity of the crucible walls.

Crucible generally are made by forming a bulk grain layer on an interior surface of a rotating crucible mold, generating a high-temperature atmosphere in the crucible cavity, and introducing inner grain and crystallization agent into the high-temperature atmosphere, fusing the inner grain to form a doped inner layer.

The following sections describe in more detail the structure, methods for manufacture, and operating modes of the present crucibles.

Structure of Doped-Layer Crucibles

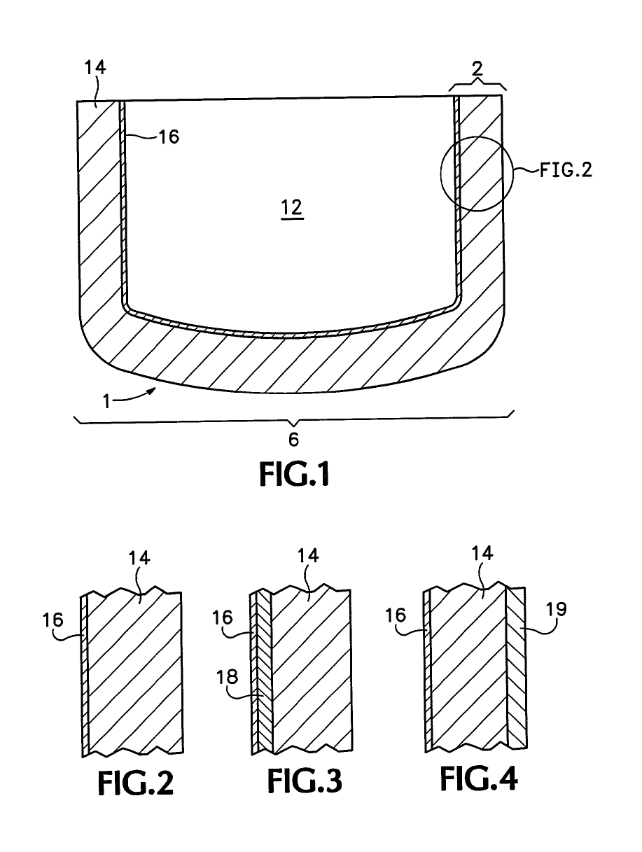

One embodiment of the crucible is shown in FIGS. 1-2. A silica glass crucible 1 has a wall 2 defining an interior cavity 12. The wall 2 comprises side wall portion 4 and bottom wall portion 6.

The side wall portion 4 of this embodiment comprises bulk layer 14 of pure silica and inner layer 16 formed as the inner structure of side wall portion 4 and bottom wall portion 6. Bulk layer 14 generally is a translucent glass layer substantially comprised of silica.

Inner layer 16 consists essentially of fused doped silica and has a thickness in the range of 0.2 mm-1.0 mm. The inner layer preferably is free of bubbles, as bubbles entrapped within the inner layer may generate fracture-induced particles as the layer crystallizes. Such particles can dissociate or break away from the inner surface as the bubble expands and as the inner surface erodes or dissolves into the silicon melt. These particles can cause loss of the single-crystal structure in the silicon ingot.

Crystallization agent is distributed within fused silica inner layer 16. The crystallization agent can be selected from the group consisting of aluminum, barium, strontium and titanium.

Crystallization agent can be in a variety of chemical forms, such as elemental (e.g. Al) or an organic or inorganic compound such as an oxide, hydroxide, peroxide, carbonate, silicate, oxalate, formate, acetate, propionate, salicylate, stearate, tartrate, fluorine, or chlorine. Preferably, crystallization agent is an oxide, hydroxide, carbonate or silicate.

Distribution within inner layer 16 of crystallization agent acts to promote crystallization of inner layer 16. The operational modes of the present crucibles are discussed more fully below.

In other embodiments, inner layer 16 can be formed on transition layer 18, the latter constructed of synthetic silica glass or pure silica glass (FIG. 3). Side wall portion 4 of this embodiment comprises bulk layer 14, transition layer 18 and inner layer 16. As in the embodiment of FIGS. 1-2, bulk layer 14 typically is translucent silica glass and inner layer 16 likewise is doped as described.

Transition layer 18 can be non-doped silica glass, made from natural or synthetic silica grain. Alternatively, however, various materials can be employed in transition layer 18. For example, transition layer 18 also can be a doped layer. Crystallization agent therein can be the same or different than that used in inner layer 16.

In the alternative embodiment of the crucible shown in FIG. 4, outer layer 19 also is formed on the outer aspect of side wall portion 4. In one embodiment, outer layer 19 is approximately 0.5-2.5 mm in thickness and can be doped with aluminum, barium, strontium or titanium. As well, a mixture of these agents can be effectively employed. Crystallization agent in outer layer 19 is generally in the range of about 50-500 ppm.

In the crucible as represented in FIG. 4, side wall portion 4 typically has a thickness of approximately 10.0 mm, of which bulk layer 14 comprises 6.5-9.4 mm, inner layer 16 comprises 0.2-1.0 mm, and outer layer 19 comprises the remaining 0.5-2.5 mm.

Bottom wall portion 6 can be constructed so as to have a similar structure to side wall portion 4 of FIGS. 2-4, but is preferably formed without outer layer 19.

It should be apparent that a crucible can be constructed having inner layer 16, transition layer 18, bulk layer 14, and outer layer 19.

Methods for Manufacturing Doped-Layer Crucibles

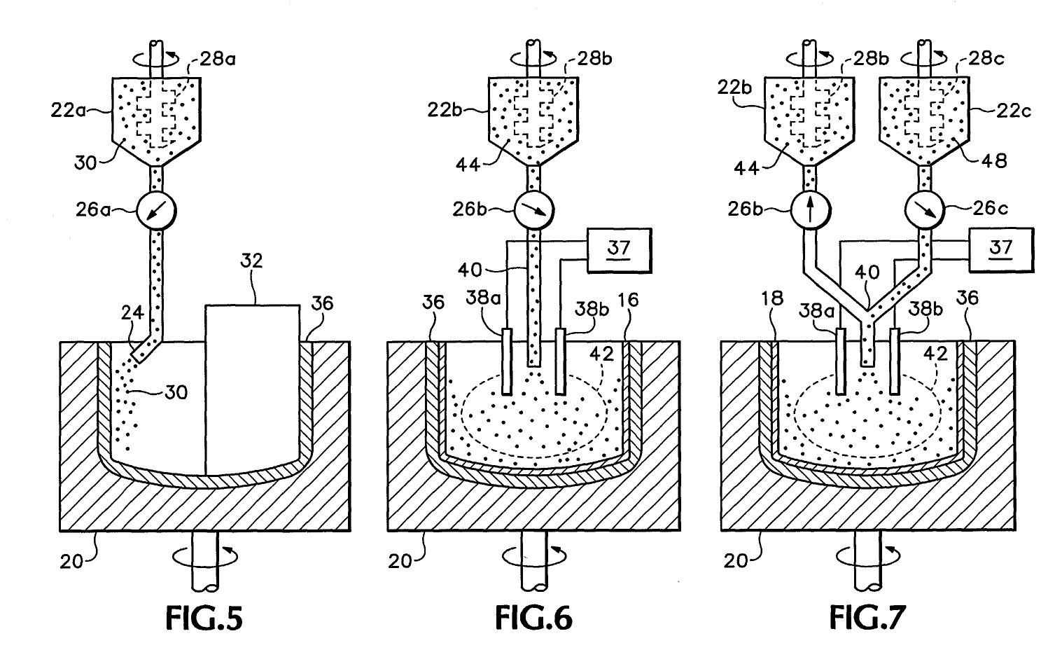

A method is disclosed herein for making a doped inner layer adapted to devitrify during a CZ run. The method shown in FIGS. 5-6 is for making the crucible embodiment shown in FIGS. 1-2.

A general method for making fused quartz glass crucibles is taught in U.S. Pat. No. 5,174,801 (to Matsumura et al.). The method generally includes forming a crucible body from silica powder in a rotating mold (FIG. 5), heating the crucible body at the interior cavity thereof to at least partially melt the body and provide a crucible basic structure.

A high-temperature atmosphere is formed in the interior cavity of the crucible structure, and inner silica grain is supplied into the high-temperature atmosphere (FIG. 6). The inner silica grain at least partially melts and deposits on the inner wall surface of the crucible basic structure, thereby forming a transparent synthetic silica glass inner layer of a predetermined thickness.

The present method for manufacturing a crucible suitable for use in formation of a silicon crystal adapts the above method to form a crucible having inner layer 16 doped with crystallization agent.

To make the crucible embodiment shown in FIGS. 1-2, bulk grain layer 36 is first formed by flowing bulk silica grain 30 from bulk silica grain hopper 22a through flow regulating valve 26a and feed tube 24 into rotating mold 20 (FIG. 5).

Bulk silica grain 30 is preferably pure quartz grain. Hopper stirring blade 28a can be used to stir bulk silica grain 30 in hopper 22a and facilitate flow therefrom. Spatula, 32 is shaped to conform to the inner surface of the mold, is generally used to shape introduced bulk silica grain. In this manner, bulk grain layer 36 can be formed to a selected thickness.

The method proceeds with fusion of formed bulk silica layer 36 (FIG. 6). An electrode assembly, including power source 37 and electrodes 38a,38b, is positioned partially within the interior cavity of mold 20. An electric arc is produced between electrodes 38a,38b, e.g., by supplying 250-350V and approximately 1800A direct current. A high-temperature atmosphere 42 is thereby generated within the mold interior. This high-temperature atmosphere 42 is sufficient to fuse the formed bulk grain layer 36 in the mold.

Fusion proceeds through formed bulk grain layer 36 from proximal to distal relative to electrodes 38a,38b. The progressive fusion through the silica grain layer according to this technique is known to those skilled in the art, for example, as disclosed in U.S. Pat. Nos. 4,935,046 and 4,956,208 both to Uchikawa et al.

Contemporaneous with fusion of the surface of formed bulk grain layer 36, inner silica grain 44 is flowed from inner silica grain hopper 22b through feed tube 40 and into the high-temperature atmosphere 42. Inner grain flow regulating valve 26b can be utilized to control the flow rate of inner silica grain 44. Hopper stirring blade 28b can be used as described above.

Inner silica grain 44 consists essentially of pure silica grain, such as natural silica grain washed to remove contaminants, doped with crystallization agent. Alternatively, synthetic silica grain doped with crystallization agent can be used.

The high-temperature atmosphere 42 produced by the electrode arc creates a very strong plasma field, at least partially melting inner silica grain 44. The at least partially molten inner silica grain 44 is propelled outward and fuses to the sides and bottom of formed bulk grain layer 36/fused bulk layer 14 to form inner layer 16.

In FIG. 6, the bulk layer is numbered as 36 representing bulk grain layer for convenience. At this stage in the method, of course, this layer is actually a changing combination of fused bulk layer 14 and unfused bulk grain layer36.

Inner layer 16 is substantially continuously formed during the time that inner silica grain 44 is flowed into the high-temperature atmosphere 42 and fused to bulk layer 14. Inner layer 16 thus formed is essentially transparent and bubble-free. The thickness of inner layer 16 can be controlled by the introduction rate of inner silica grain and by the period of inner grain flow during fusion.

A method for making a crucible having both inner layer 16 and transition layer 18 comprises the steps shown in FIGS. 5 and 7-8.

After formation of bulk grain layer 36 (FIG. 5), the electrode assembly is positioned within the crucible interior cavity. Transition grain 48 is supplied from transition grain hopper 22c through flow controlling valve 26c (FIG. 7). Hopper stirring blade 28c can be employed similarly to stirring blades 28a,28b.

Transition silica grain 48 is at least partially melted in the high-temperature atmosphere 42 and fuses on formed bulk grain layer 36/fused bulk layer 14 to form transition layer 18. The thickness of transition layer 18 also can be controlled by regulating the rate and time of transition silica grain 48 flow.

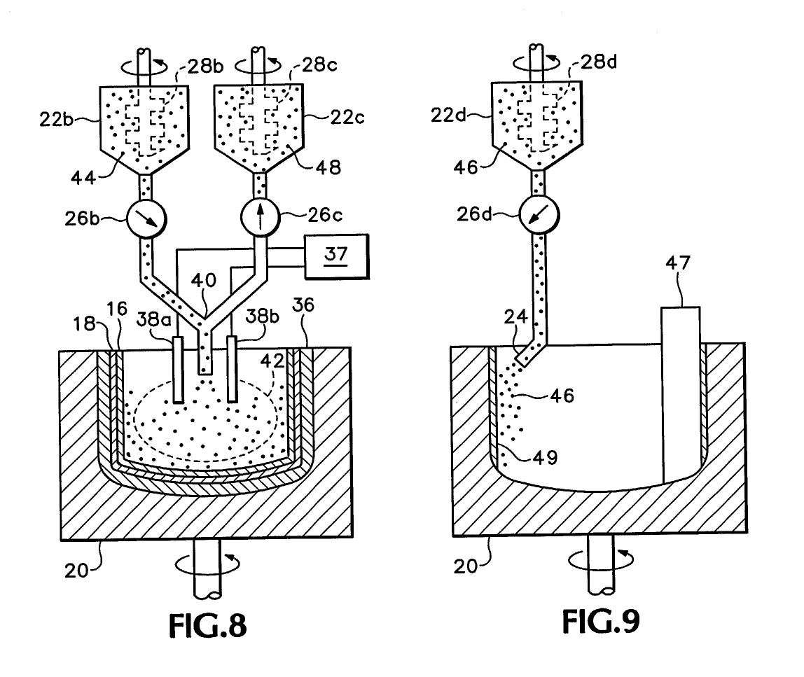

After formation of transition layer 18, inner silica grain 44 is then introduced into the high-temperature atmosphere 42 (FIG. 8). As before, inner silica grain 44 is at least partially melted and deposited as inner layer 16 on transition layer 18.

Crystallization agent-doped inner layer can be formed on a variety of transparent transition layer compositions. For example, transition layer 18 can be a pure silica layer or a doped layer. The crystallization agent-doped inner layer can be deposited on a transparent layer made of synthetic silica grain or pure silica grain (i.e., purified natural quartz).

A similar method is used to construct a crucible having outer layer 19 (FIG. 4). Outer grain layer 49 is first formed in rotating mold 20 (FIG. 9). Outer grain hopper 22d communicates via feed tube 24 with the interior of mold 20. Feed tube 24 can employ valve 26d to regulate the flow of outer silica grain 46 from hopper 22d to the interior of the mold. The thickness of outer grain layer 49 can be controlled using spatula 47. Manufacture of the crucible then proceeds as described above.

Outer layer 19 also can be doped with crystallization agent. Doped outer layer 19 can be constructed to readily crystallize and thereby improve dimensional stability at high temperatures, without affecting or contaminating the silicon melt.

Aluminum typically is less costly than other compounds, and disposal of unfused aluminum-doped outer silica grain is more environmentally convenient. A mixture of pure silica grain and aluminum-doped outer silica grain 46 therefore is preferred, although other dopants or mixed grains can also be employed.

Methods of Crystallization Agent Introduction

In the embodiment of the present method thus described, inner silica grain 44 is doped with the crystallization agent. As has been mentioned, the crystallization agent can contain aluminum, barium, strontium or titanium, in either elemental form or as a compound. Oxides and nitrides are two preferred forms of the crystallization agent in compound form.

A mixture of doped silica grain and undoped silica grain can also be employed, so long as the selected final agent concentration is achieved.

When synthetic silica grain is used as the undoped silica grain in the mixture, it is observed that the crystallization promoting strength of the crystallization agent is enhanced. Glass formed of synthetic silica is softer than natural silica glass (i.e., fused quartz glass). The softer matrix of synthetic silica glass is more favorable to crystallization, likely because of an increased tolerance (i.e., decreased structural resistance) to the volume changes associated with the phase transition from amorphous silica glass to crystalline silica such as cristobalite. As a result, similar level of transformation can be obtained at a lower doping level when synthetic silica grain is incorporated in fused inner layer 16 or outer layer 19.

By preparing a silica sol containing crystallization agent, uniformly doped silica gel can be obtained. This gel can be another example of the doped grain. The gel preferably is calcined to convert it to pure silicon dioxide.

Alternatively to doping of silica grain, crystallization agent can be borne on silica grain by coating silica grain or by formation of an agent-bearing silica gel. The coated grain can formed by coating pure silica grain with an organic material, e.g., an alcoholate.

In another alternative introduction scheme, crystallization agent can be mixed and introduced contemporaneously with undoped silica grain, such as either natural or synthetic silica grain. For example, barium carbonate (BaCO₃) can be added to inner silica grain 44 in hopper 22b. Mixing blade 28b can be used to ensure uniform blending of barium carbonate and inner silica grain. The mixture of inner silica grain and barium carbonate then can be flowed into the high-temperature atmosphere 42, as described above.

During fusion of inner silica grain 44, crystallization agent can be supplied into the high-temperature atmosphere 24 as inorganic powder, e.g., oxide (e.g., BaO), complex oxide (e.g., TiBaO₃), nitride (e.g., BaN₂), chloride (e.g., BaCl₃), or as a complex or mixture of a plurality of such compounds. Organic compounds, which convert to one of the above-mentioned species at the high temperatures of crucible fusion, can be used in a similar manner.

In an alternative embodiment of the method, crystallization agent can be separately introduced from a dedicated hopper into the high-temperature atmosphere 24 contemporaneous with introduction of inner silica grain 44. Valves controlling flow of contents from inner grain hopper and agent hopper, similar to those previously described herein, can both be opened so as to flow concurrently.

In yet another example, crystallization agent can be in liquid form, e.g., an aqueous solution of barium hydroxide (Ba(OH)₂) or barium chloride (BaCl₂). Liquid solution can be introduced into inner silica grain 44 prior to or contemporaneous with introduction of inner silica grain 44 into the high-temperature atmosphere 24.

Liquid solution alternatively can be introduced directly into the high-temperature atmosphere 24 contemporaneous with flow of inner silica grain 44, for example by an injector generally positioned adjacent the end of flow tube 40 proximate the high-temperature atmosphere 24. Liquid solution can be either aqueous or organic, so long as the chosen solvent does not present a potential source of ingot contamination.

Crystallization agent in liquid solution can also be applied to a formed grain layer prior to fusion. An organic compound, organic solution or aqueous solution of crystallization agent can be sprayed onto formed outer grain layer 49. A benefit of application of agent to a formed grain layer is control of localization of agent to a specific region of the layer. For example, crystallization agent can be applied to only the inner aspect of side wall portion 4 or bottom wall 6, to the entire (side and bottom) inner aspect of side wall portion4 and bottom wall portion 6, or only to that inner aspect of side wall portion 4 that is below the contemplated melt-line (melt-line is the line where molten silicon contacts the crucible interior wall after melt-down).

Using the above method in which the crystallization agent is introduced concurrently with but separate from the inner silica grain, transition silica grain 48 can also be employed as inner silica grain 44. For example, transition silica grain 48 can be flowed into the high-temperature atmosphere 24 to form transition layer 18 as described above. Transition hopper flow is stopped, and then both transition silica grain 48 and barium compound are flowed simultaneously into the high-temperature atmosphere 24 to form inner layer 16.

In a similar embodiment, pure inner silica grain 44 can be flowed as originally described, and then barium carbonate flow can be initiated contemporaneous with still-flowing inner silica grain 44 to form inner layer 16 having barium carbonate therein. Barium carbonate flow rate can be varied, such that a gradient is formed in inner layer 16 from the inner surface to bulk layer 14. Such an embodiment is substantially equivalent to an crucible having bulk layer 14, transition layer 18 and inner layer 16, wherein inner layer 16 has an agent gradient that is very low in the region proximate bulk layer 14 and higher in the region proximate the crucible interior cavity 12.

Operational Modes of Doped-Layer Crucibles

Selection of the doping element for use in inner layer 16 is dictated by the operational mode desired. Each of the agents possesses unique crystallization-promoting strengths and, in tandem with agent doping levels, can be used to control the rate and extent of silica crystallization of inner layer 16.

A discussion of the operational modes and the use of various agents to achieve these modes begins with a review of the rosette phenomenon observed on the inner surface of a crucible used in a CZ process. From an operational perspective, it is desirable to retain a smooth surface primarily on that portion of the inner layer whose surface contacts the melt when the crucible is used in silicon ingot formation. It should therefore be noted that, in the following discussion, the crucible “inner layer” and “inner surface” refer to this operationally more significant portion of the inner layer.

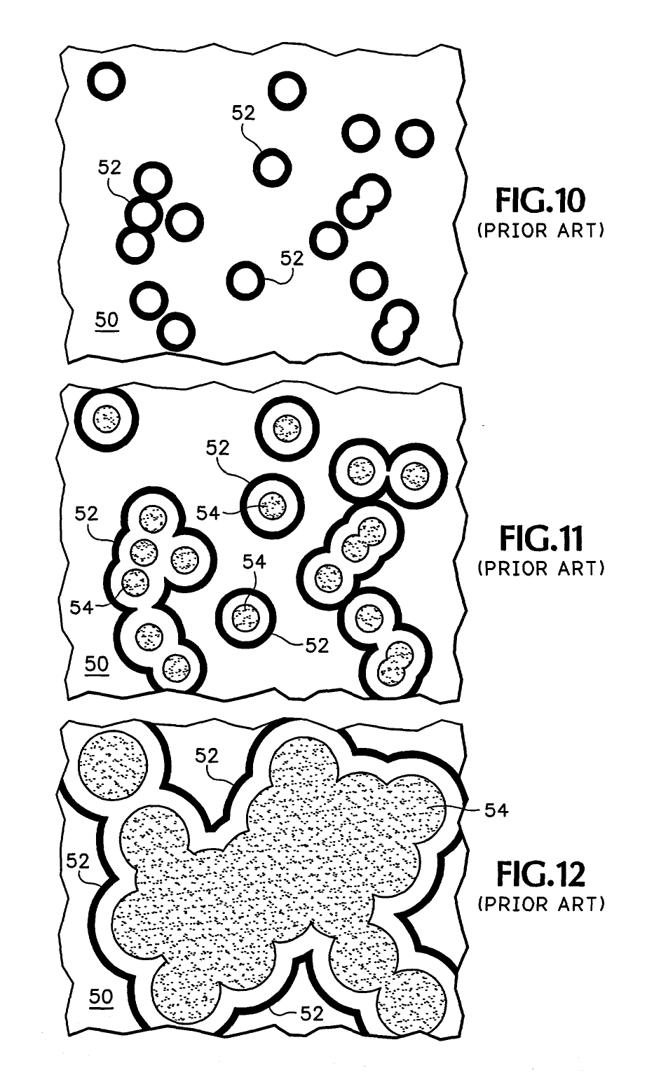

In more detail, the rosette phenomenon observed on the inner surface of a prior art crucible in shown in FIGS. 10-14. FIG. 10 depicts an inner surface 50 of a crucible, on which have formed a plurality of rosettes where the crucible surface 50 contacts the silicon melt. A rosette generally has a ring 52; the ring and the region inside the ring are cristobalite 56.

During a CZ-process, the rosettes grow in area, spreading to cover an increasing percentage of the inner layer surface 50, as shown in FIG. 11. As the rosette grows, a rough texture 54 appears in the center. The rough surface area 54 within the boundaries of the rosettes also expands across the crucible inner surface. FIG. 12 shows the state of an exemplary crucible inner surface 50 of the prior art later in the CZ-process. Rosettes merge and the rough surface area 54 is increased. As discussed above, inner surface roughening adversely impacts the crystalline structure of the growing silicon ingot.

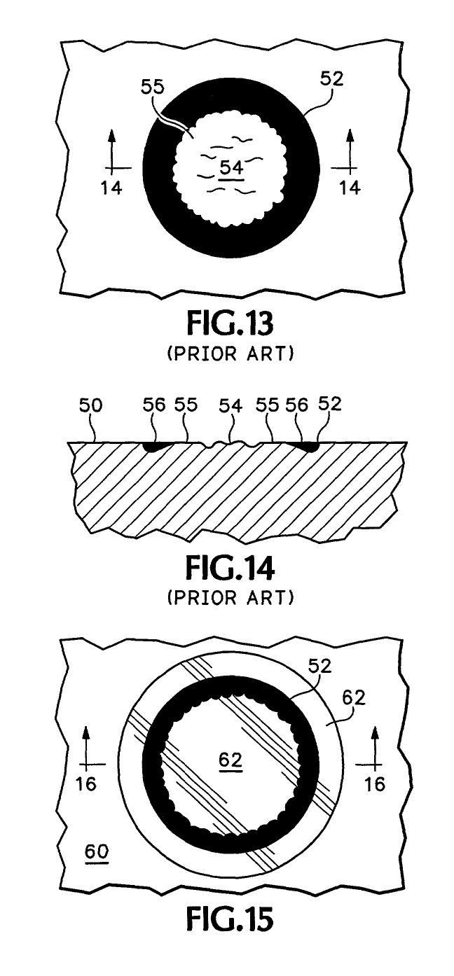

Enlarged top and cross-sectional views of a rosette of the prior art are shown in FIGS. 13-14. The center of the rosette has a rough surface texture 54 surrounded by cristobalite (crystalline silica) 56, the latter of which is seen to extend into the crucible wall from inner surface 50. The cristobalite ring 52 is decorated with brown materials and normally is observed as a brown ring on the inner surface of a used crucible. In some rosettes of the prior art, a small smooth surface boundary 55 exists between the rough area 54 and the inner edge of the ring 52.

Regarding rosettes and concomitant surface roughening, the present invention employs a combination of factors, discussed below, to provide a crucible inner layer adapted to operate according to one of three crystallization modes, designated herein as FULL, SMOOTH, and CORONA. In each of these modes, the crucible is suitable for use in an extended CZ-process without inner surface roughening or significant dissolution.

“FULL” Mode. In this mode, the inner surface of the crucible is adapted to be crystallized when heated and before contacted with the silicon melt. In this mode, generation of rosettes is suppressed, i.e., rosettes are not observed during or after a CZ run.

The inner surface of a FULL mode crucible therefore is covered with β-cristobalite after heating and before melt-down of the silicon. As a result, rosettes are not formed by a reaction between the silicon melt and crystalline silica. Lack of rosette generation means roughening of the inner surface is suppressed and the crucible inner surface remains smooth.

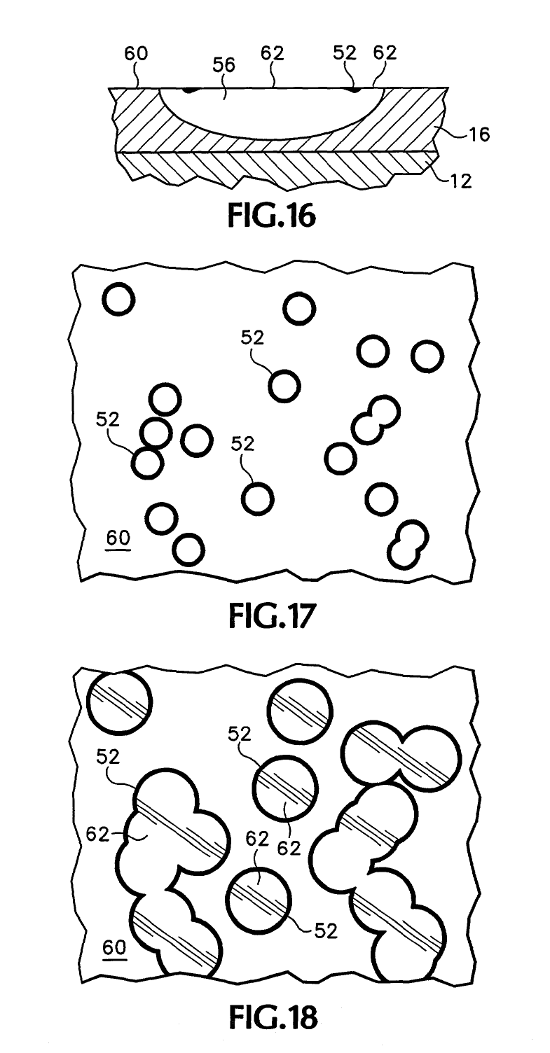

“CORONA” Mode. The second mode of maintaining a smooth crucible inner surface is to stifle expansion of rosettes (FIGS. 15-16). Ring 52 of a rosette is cristobalite, which may act as a nucleation site to grow crystalline silica 56 in the silica glass of inner layer 16. However, there exists a disparity in phase transition propagation rates between the central region of the rosette and the corona around the ring 52.

A cristobalite corona or halo grows faster than growth of cristobalite ring 52, such that ring 52 is surrounded by crystalline silica 56. When ring 52 is so bounded by crystalline silica 56, it is observed that the growth rate of the rosette is decreased by at least 50%.

This crystallization rate disparity is exploited, resulting in rings surrounded by corona-like crystalline phase “coronas” and suppression ring growth. Consequently, phase transition of inner layer 16 from silica glass to β-cristobalite proceeds slowly (i.e., rapid crystallization does not occur as it does in “FULL” mode) and a large amount of the original glass is retained for a prolonged time.

The combination of a large smooth surface 60 and slow-growing smooth cristobalite surface 56 combine to maintain a substantially vitreous inner layer for a longer period than in a conventional crucible. The inner surface of a “CORONA” crucible does not degrade as rapidly as in the prior art.

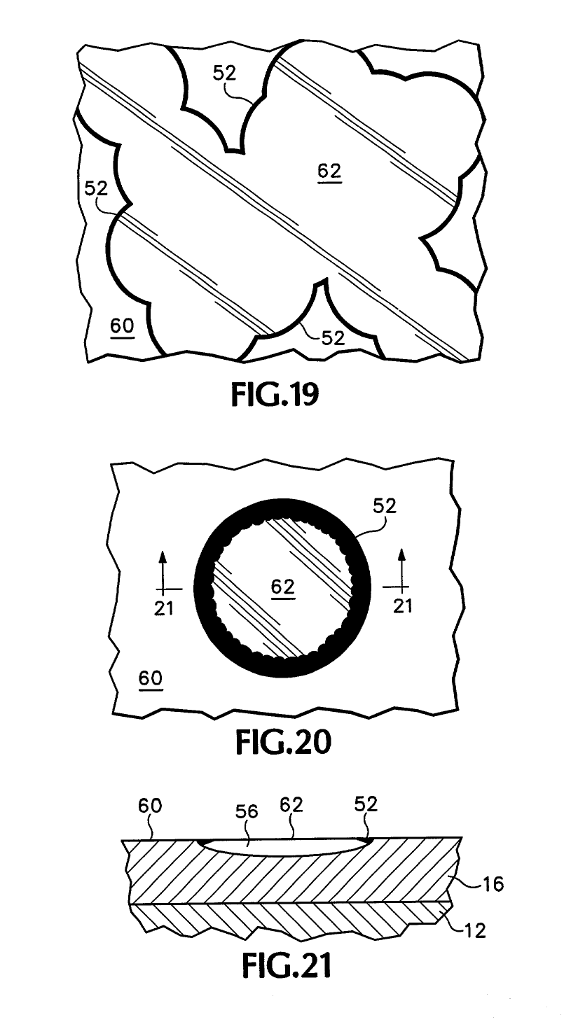

“SMOOTH” Mode. A third mode of maintaining crucible usefulness is to prevent generation of rough area 54. Rosettes are observed to form on the inner surface of a “SMOOTH” mode crucible (FIG. 17) similarly to those formed on walls of a prior art crucible (compare with FIG. 10). “SMOOTH” crucible rosettes continue to grow and merge (FIGS. 18-19), as occurs on prior art crucible inner surfaces 50.

Nevertheless, silica crystallization within inner layer 16 occurs more slowly than in either “FULL” or “CORONA” mode crucibles. Although inner layer 16 does not undergo a phase transition as rapidly, the vitreous silica layer nevertheless is not observed to undergo conventional, undesirable devitrification (i.e., roughening and potential degradation). The “SMOOTH” crucible inner surface 60 retains a smooth texture 62.

FIGS. 20-21 show a plan view and an enlarged cross-sectional view of a rosette growing on inner surface 62 of a “SMOOTH” crucible. The rosette comprises ring 52 at the outer boundary of the rosette, within which is found cristobalite 56. The cristobalite 56 extends into inner layer 16.

In contrast to the crucible inner surface 50 of the prior art (FIGS. 13-14), the “SMOOTH” crucible retains a smooth surface within ring 52 and rosette. Even after the “SMOOTH” crucible surface is covered by merged rings, it is observed that roughening is substantially prevented as compared to conventional crucibles.

Selection and Control of Operational Modes

The present invention permits selection among these three modes to suit the particular application desired. A crucible can be constructed to operate in one of the above three operational modes by a variety of factors, including crystallization agent identity and level, manner in which the agent is introduced into the high-temperature atmosphere, and post-fusion handling of the crucible.

Crystallization agent and control of cristobalite formation. The rate of cristobalite growth is a primary means by which mode selection is accomplished. Crystallization will occur most rapidly in “FULL” mode, then “CORONA” mode, and lastly “SMOOTH” mode.

In terms of strength in silica crystallization promotion, group 2A elements are the strongest, followed by group 3B elements, and then group 4A elements. Thus, of the above-mentioned crystallization agents at equal doping levels, however, the strongest is strontium (group 3B), followed by barium (group 2A), then aluminum (group 3B), and then titanium (group 4A).

A combination of two or more of these elements in a mixture or as a multi-layer crucible can also be employed. Alkaline elements (i.e., group IA members such as Li, Na, K) can be used but are not preferred because they tend to diffuse and will not be confined within the doped layer.

Silica crystallization also is affected by crystallization agent level. Generally, higher doping levels enhance the cristobalite growth rate. Using aluminum as an example, cristobalite formation proceeds more rapidly in a layer doped at 250 ppm than in a layer doped at 25 ppm.

The cristobalite growth rate is increased using a thinner inner layer. A crucible constructed with a 0.2 mm thick inner layer 16 demonstrated faster phase transition than did a crucible possessing a 1.2 mm thick layer.

Faster cristobalite growth generally results from non-homogeneous doping, and especially with non-homogeneous doping using a mixture comprising synthetic silica grain (amorphous) rather than crystalline silica grain (quartz).

As stated, the above factors can be controlled to produce thereby a crucible adapted to operate in either of “FULL”, “CORONA” or “SMOOTH” mode. For simplicity, the following examples address inner layer 16, although the same principles apply to outer layer 19.

Example A: “FULL” mode crucible. An exemplary crucible operative in “FULL” mode uses a relatively strong crystallization-promoting agent or a relatively high doping level. For example, natural inner silica grain 44 can be doped with barium and flowed to form inner layer 16 with a crystallization agent level of about 70 ppm. Alternatively, barium-doped natural inner silica grain and pure synthetic silica grain can be blended and used to form an inner layer having barium distributed therein at about 20 ppm.

Inner layer 16 of a “FULL” mode crucible typically has a thickness in the range of 0.2-1.2 mm. The precise thickness of inner layer 16 must be determined in concert with the type of silica grain, the specific crystallization agent and its method of agent introduction.

Alternative “FULL” mode crucibles can be manufactured with fusion of inner silica grain 44 that has been coated-rather than doped-with crystallization agent. Use of coated inner silica grain 44 results in non-homogeneous distribution of crystallization agent within inner layer 16. Similarly, substantially contemporaneous flow of inner silica grain 44 and crystallization agent also non-homogeneously distributes agent within the fused layer 16.

Example B: “CORONA” mode crucible. A crucible adapted to operate in “CORONA” mode typically has a crystallization agent of moderate crystallization-promoting strength within its inner layer at a lower to moderate doping level. For example, aluminum-doped natural silica inner grain 44 can be used to form inner layer 16. Aluminum preferably is distributed within inner layer 16 in the range of 40-80 ppm. The doped layer can have a thickness in the range of about 0.5-1.2 mm

Because it is undesirable to confer rapid crystallizing ability on the entire inner layer in this mode, strong crystallization promoters such as barium and strontium can be used but are not preferred for use in this mode. Similarly, natural silica grain is preferred over synthetic silica grain for use as inner silica grain 44. It is readily apparent, however, that the addition of synthetic silica grain to doped inner grain 44 (or use of doped synthetic inner silica grain) can permit use of a weaker crystallization agent.

As well, doped silica grain is preferred over coated silica grain or contemporaneous introduction, so that crystallization promoter is substantially evenly distributed within inner layer 16. This preference remains despite formation of a crystallization agent gradient distribution with inner layer 16, as described in an alternative method above.

Example C: “SMOOTH” mode crucible. A crucible operating this mode retains a smooth surface by slow progression of silica crystallization in the inner aspect of the side wall portion 4 and bottom wall portion 6. Inner layer 16 of a “SMOOTH” crucible preferably has a crystallization agent with weak to moderate crystallization promoter strength. Crystallization agent is distributed within inner layer 16, for example, 100 ppm titanium in a doped layer made of fused natural inner silica grain.

Depending on the particular crystallization agent chosen and the use of synthetic inner silica grain 44, thinner inner layers can be formed that operate efficaciously.

Crucible design should preferably be tuned to the conditions of the contemplated CZ-process, and specifically to the heating schedule of the process.

The methods disclosed above distribute a crystallization agent within a crucible inner layer, rather than coating the interior surface of a crucible with a devitrification promoter. Layer doping, has several merits over conventional coating methods.

The present method enables the crystallization agent concentration in inner layer 16 or outer layer 19 to be finely controlled. In a described embodiment, inner silica grain 44 is doped with barium prior to its introduction and fusion. The amount of crystallization agent contained in the agent-doped grain can be precisely determined in advance by analysis. Crystallization agent level in inner layer 16 can thereby be finely controlled by, for example, mixing doped silica grain and pure silica grain in the hopper.

The thickness of inner layer 16 also can be manipulated by changing inner silica grain flow rate or flow time. No loss of crystallization promoter has been observed, e.g., loss due to sublimation, when the manufacturing methods were carried out. Substantially all of the introduced agent was found to be fixed within inner layer 16.

Moreover, doping of a three-dimensional layer permits a smaller total amount of crystallization agent to be used compared to the prior art. Calculations were performed, based on the amount of crystallization agent introduced into the high-temperature atmosphere and the inner surface area of the crucible. Data reveal that barium-doped crucibles constructed according to the present disclosure operate efficaciously with approximately one-tenth the “devitrification promoter” used in surface-coated crucibles of prior art efforts.

Because the crystallization agent is distributed and fused within the silica glass, crucibles also can be machined to dimensions, cleaned or etched, and handled with the same procedures as for normal pure silica crucibles. No additional post-manufacture processing or special handling of crucibles is required.

For example, unfused grain remaining on the outside of a conventional crucible can be cleaned by sand-blasting, followed by rinsing with water. After cutting the crucible to specified dimensions, it can be cleaned by etching with dilute hydrofluoric acid and rinsing with pure water. The crucible then can be dried in a clean air bath, then bagged and boxed for shipment.

A crucible constructed according to the present disclosure can be cleaned or otherwise handled without removal of crystallization agent from inner layer 16 or outer layer 19.

A person skilled in the art will be able to practice the present invention in view of the description present in this document, which is to be taken as a whole. Numerous details have been set forth in order to provide a more thorough understanding of the invention. In other instances, well-known features have not been described in detail in order not to obscure unnecessarily the invention.

While the invention has been disclosed in its preferred form, the specific embodiments thereof as disclosed and illustrated herein are not to be considered in a limiting sense. Indeed, it should be readily apparent to those skilled in the art in view of the present description that the invention can be modified in numerous ways. The inventor regards the subject matter of the invention to include all combinations and subcombinations of the various elements, features, functions and/or properties disclosed herein.

What is claimed is:

1. A crucible adapted for use in formation of a silicon crystal, comprising:
a crucible wall including a bottom wall and a side wall; and
an inner layer formed on an inner portion of said crucible wall, said inner layer having distributed therein a crystallization agent containing an element selected from the group consisting of barium, aluminum, titanium and strontium.

2. The crucible of claim 1, wherein said crystallization agent is titanium distributed in the inner layer at a level in the range of 50-200 ppm.

3. The crucible of claim 2, wherein titanium is distributed in the inner layer at a level in the range of 80-160 ppm.

4. The crucible of claim 2, wherein the inner layer has a thickness in the range of 0.2-1.2 mm.

5. The crucible of claim 1, wherein said crystallization agent is strontium distributed in the inner layer at a level in the range of 20-160 ppm.

6. The crucible of claim 5, wherein strontium is distributed in the inner layer at a level in the range of 25-70 ppm.

7. The crucible of claim 5, wherein the inner layer has a thickness in the range of 0.2-1.2 mm.

8. The crucible of claim 1, wherein said inner layer having distributed therein a crystallization agent containing a plurality of elements selected from the group consisting of barium, aluminum, titanium and strontium.

9. A method for manufacturing a crucible adapted for use in formation of a silicon crystal, comprising:
forming a bulk grain layer on an interior surface of a rotating crucible mold, said bulk grain layer having a bottom portion, a side portion, a bulk grain layer interior surface and defining a crucible cavity; and
generating a high-temperature atmosphere in the crucible cavity; and
introducing inner grain and crystallization agent into the high-temperature atmosphere.

10. The method of claim 9, wherein crystallization agent contains an element selected from the group consisting of barium, aluminum, titanium and strontium.

11. The method of claim 9, wherein crystallization agent comprises a compound operative to be converted by the high-temperature atmosphere into an oxide, nitride, chloride or halide.

12. The method of claim 9, wherein introducing inner grain and crystallization agent comprises introducing doped inner grain, said doped inner grain being doped with the crystallization agent.

13. The method of claim 12, wherein doped inner grain comprises doped natural silica grain.

14. The method of claim 12, wherein doped inner grain comprises doped synthetic silica grain.

15. The method of claim 12, further comprising introducing pure inner grain contemporaneous with the doped inner grain.

16. The method of claim 15, wherein pure inner grain comprises pure natural inner grain.

17. The method of claim 15, wherein pure inner grain comprises pure synthetic inner grain.

18. The method of claim 9, wherein introducing inner grain and crystallization agent comprises introducing crystallization agent-coated inner grain.

19. The method of claim 18, wherein coated inner grain comprises coated natural silica grain.

20. The method of claim 18, wherein coated inner grain comprises coated synthetic silica grain.

21. The method of claim 18, wherein crystallization agent-coated inner grain comprises coated inner grain and pure inner grain.

22. The method of claim 21, wherein pure inner grain comprises pure natural inner grain.

23. The method of claim 21, wherein pure inner grain comprises pure synthetic inner grain.

24. The method of claim 9, wherein introducing inner grain and crystallization agent comprises contemporaneously introducing pure inner grain and introducing crystallization agent.

25. The method of claim 24, wherein introducing crystallization agent comprises introducing solid crystallization agent.

26. The method of claim 25, wherein introducing solid crystallization agent comprises introducing crystallization agent-doped silica gel.

27. The method of claim 24, wherein introducing crystallization agent comprises spraying liquid-phase crystallization agent.

28. A method for manufacturing a crucible adapted for use in formation of a silicon crystal, comprising:
forming a bulk grain layer on an interior surface of a rotating crucible mold, said bulk grain layer having a bottom portion, a side portion, a bulk grain layer interior surface and defining a crucible cavity;
forming an inner grain layer on the bulk grain layer interior surface;
generating a high-temperature atmosphere in the crucible cavity to at least partially melt the inner grain layer; and
introducing crystallization agent into the high-temperature atmosphere, said crystallization agent containing an element selected from the group consisting of aluminum, barium, titanium and strontium.

29. The method of claim 28, wherein crystallization agent comprises an oxide, hydroxide, peroxide, carbonate, silicate, oxalate, formate, acetate, propionate, salicylate, stearate, tartrate, fluoride, or chloride.

30. The method of claim 28, wherein introducing crystallization agent comprises introducing solid crystallization agent.

31. The method of claim 30, wherein introducing solid crystallization agent comprises introducing crystallization agent-doped silica gel.

32. The method of claim 29, wherein introducing crystallization agent comprises spraying liquid-phase crystallization agent.

33. The method of claim 29, wherein introducing crystallization agent comprises introducing inner grain containing crystallization agent.

34. The method of claim 33, wherein introducing inner grain containing crystallization agent comprises introducing crystallization agent-doped inner grain.

35. The method of claim 33, wherein introducing inner grain containing crystallization agent comprises introducing crystallization agent-coated inner grain.

36. The method of claim 33, wherein coated inner grain comprises coated natural silica grain.

37. The method of claim 33, wherein coated inner grain comprises coated synthetic silica grain.

38. A method for manufacturing a crucible adapted for use in formation of a silicon crystal, comprising:
forming a bulk grain layer on an interior surface of a rotating crucible mold, said bulk grain layer having a bottom portion, a side portion, a bulk grain layer interior surface and defining a crucible cavity;
forming an inner grain layer on the bulk grain layer interior surface;
applying crystallization agent to the inner grain layer; and
generating a high-temperature atmosphere in the crucible cavity to fuse the inner grain layer with crystallization agent distributed therein.

39. The method of claim 38, wherein crystallization agent contains an element selected from the group consisting of aluminum, barium, titanium and strontium.

40. The method of claim 38, wherein crystallization agent comprises an oxide, hydroxide, peroxide, carbonate, silicate, oxalate, formate, acetate, propionate, salicylate, stearate, tartrate, fluorine, or chlorine.

41. The method of claim 38, wherein applying crystallization agent comprises applying solid crystallization agent.

42. The method of claim 38, wherein applying solid crystallization agent comprises applying crystallization agent-doped silica gel.

43. The method of claim 38, wherein applying crystallization agent comprises spraying liquid-phase crystallization agent.

44. A crucible for use in formation of a silicon crystal, comprising:
a crucible wall including a bottom wall and a side wall; and
an inner layer formed on an inner portion of said crucible wall and adapted to, when heated, substantially crystallize.

45. The crucible of claim 44, wherein the inner layer is adapted to crystallize when heated and before contacted with the silicon charge.

46. The crucible of claim 44, wherein said inner layer has distributed therein a crystallization agent comprising barium, aluminum or strontium.

47. The crucible of claim 46, wherein barium is distributed within said inner layer in the range of 5-150 ppm.

48. The crucible of claim 46, wherein said inner layer consists essentially of natural silica and barium distributed therein in the range of 50-90 ppm.

49. The crucible of claim 46, wherein said inner layer consists substantially of synthetic silica and barium distributed therein in the range of 10-40 ppm.

50. The crucible of claim 46, wherein aluminum is distributed within said inner layer in the range of 50-500 ppm.

51. The crucible of claim 46, wherein said inner layer consists essentially of natural silica and aluminum distributed therein in the range of 80-160 ppm.

52. The crucible of claim 46, wherein said inner layer consists substantially of synthetic silica and aluminum distributed therein in the range of 50-100 ppm.

53. A crucible for use in formation of a silicon crystal, comprising:
a crucible wall including a bottom wall and a side wall; and
an inner layer of a vitreous character formed on an inner portion of said crucible wall, said inner layer adapted to, when heated, preserve the vitreous character and retard formation of a-cristobalite.

54. The crucible of claim 53, wherein said inner layer has distributed therein a crystallization agent comprising titanium or aluminum.

55. The crucible of claim 54, wherein titanium is distributed within said inner layer in the range of 40-130 ppm.

56. The crucible of claim 54, wherein said inner layer consists essentially of natural silica and titanium distributed therein in the range of 70-130 ppm.

57. The crucible of claim 54, wherein said inner layer consists substantially of synthetic silica and titanium distributed therein in the range of 40-75 ppm.

58. The crucible of claim 54, wherein aluminum is distributed within said inner layer in the range of 25-150 ppm.

59. The crucible of claim 54, wherein said inner layer consists essentially of natural silica and aluminum distributed therein in the range of 75-150 ppm.

60. The crucible of claim 54, wherein said inner layer consists substantially of synthetic silica and aluminum distributed therein in the range of 25-80 ppm.
